(19) United States
(12) Patent Application Publication
(10) Pub. No.: US 2026/0013223 A1
(43) Pub. Date: Jan. 8, 2026

(54) PIXEL ARRAY SUBSTRATE AND METHOD OF FABRICATING THE SAME

(71) Applicant: HannStar Display Corporation, Taipei City (TW)

(72) Inventors: Li Fang Chiu, Taipei City (TW); Min Sheng Chiu, Taipei City (TW)

(73) Assignee: HannStar Display Corporation, Taipei City (TW)

(21) Appl. No.: 18/908,765

(22) Filed: Oct. 7, 2024

(30) Foreign Application Priority Data
Jul. 4, 2024 (TW) 113125074

(51) Int. Cl. H01L 27/12; H01L 21/02; H01L 21/3065; H01L 21/308; H01L 21/3205; H01L 21/3213; H01L 21/77; H01L 29/417; H01L 29/45; H01L 29/66

(52) U.S. Cl. CPC H10D 86/0231; H01L 21/02532; H01L 21/3065; H01L 21/308; H01L 21/32051; H01L 21/32136; H01L 21/32139; H01L 21/77; H10D 30/0321; H10D 30/6729; H10D 30/6737; H10D 30/6743; H10D 86/0221; H10D 86/451; H10D 86/60; H10D 86/021

(57) ABSTRACT

A method of fabricating a pixel array substrate includes forming a semiconductor layer on a substrate, forming a metal layer stack on the semiconductor layer, forming a photoresist pattern on the metal layer stack, and removing part of the metal layer stack and the semiconductor layer not covered by the photoresist pattern at one time using a dry etching process to form a source, a drain, and a semiconductor pattern of an active device. The metal layer stack includes a first titanium layer, an aluminum layer, and a second titanium layer. The semiconductor pattern has a groove located between the source and the drain. The source and the drain respectively have a source edge and a drain edge opposite to each other, which defines two opposite side walls of the groove respectively. A pixel array substrate produced by using the method of fabricating the pixel array substrate is also disclosed.

### CROSS-REFERENCE TO RELATED APPLICATION

This application claims the priority benefit of Taiwan application serial no. 113125074, filed on Jul. 4, 2024. The entirety of the above-mentioned patent application is hereby incorporated by reference herein and made a part of this specification.

### BACKGROUND

### Technical Field

This disclosure relates to a substrate and a method of fabricating the same, in particular to a pixel array substrate and a method of fabricating the same.

### Description of Related Art

In the current display panels using amorphous silicon thin-film transistors, their sources and drains are mostly patterned and made of metal stacked structures of molybdenum, aluminum, and molybdenum. The patterning process requires both dry etching and wet etching. However, the critical-dimension bias (CD bias) after etching may be too large, resulting in an increased risk of breakage and affecting the production yield. From another point of view, it is also difficult to realize the fine line width design of the device.

### SUMMARY

The disclosure provides a method of fabricating a pixel array substrate, capable of forming components with smaller critical-dimension bias (CD bias).

The disclosure provides a pixel array substrate with a large design margin for component line width.

The method of fabricating the pixel array substrate of the disclosure includes the following. A semiconductor layer is formed on a substrate. A metal layer stack is formed on the semiconductor layer. A photoresist pattern is formed on the metal layer stack. A part of the metal layer stack and the semiconductor layer not covered by the photoresist pattern are removed at one time using a dry etching process to form a source, a drain, and a semiconductor pattern of an active device. A material of the semiconductor layer includes amorphous silicon semiconductor. The metal layer stack includes a first titanium layer, an aluminum layer, and a second titanium layer. The source and the drain have a source edge and a drain edge opposite to each other respectively. The semiconductor pattern has a groove between the source and the drain, and the source edge and the drain edge define two opposite side walls of the groove respectively.

The pixel array substrate of the disclosure includes a substrate and multiple active devices. The active devices are disposed on the substrate, and each includes a gate, a semiconductor pattern, a source, and a drain. The gate is located between the semiconductor pattern and the substrate. The drain and the source are in contact with two different areas of the semiconductor pattern respectively. A material of the semiconductor pattern includes amorphous silicon semiconductor. The source and the drain each includes a first titanium layer, an aluminum layer, and a second titanium layer sequentially stacked on the semiconductor pattern. The source and the drain have a source edge and a drain edge opposite to each other respectively. The semiconductor pattern has a groove located between the source and the drain, and the source edge and the drain edge define two opposite side walls of the groove respectively.

Based on the above, in the method of fabricating the pixel array substrate according to an embodiment of the disclosure, a metal layer stack composed of two titanium layers and one aluminum layer is formed on the amorphous silicon semiconductor layer. The channel, the source, and the drain of the semiconductor pattern formed by using the dry etching process to remove a part of the metal layer stack and a part of the amorphous silicon semiconductor layer at one time may have a smaller critical-dimension bias (CD bias), helping to increase the design margin of the component line width of the pixel array substrate.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate example embodiments of the disclosure and, together with the description, serve to explain the principles of the disclosure.

FIG. 1 is a schematic front view of a pixel array substrate according to an embodiment of the disclosure.

FIG. 2 is a schematic cross-sectional view of a display panel according to an embodiment of the disclosure.

FIG. 3 is an enlarged schematic view of a partial area of FIG. 2.

FIG. 4 to FIG. 6 are flow charts of a method of fabricating a pixel array substrate of FIG. 2.

FIG. 7A to FIG. 7E and FIG. 8A to FIG. 8D are schematic cross-sectional views of a fabricating process of the pixel array substrate of FIG. 2.

### DESCRIPTION OF THE EMBODIMENTS

The aforementioned and other technical contents, features, and functions of the disclosure will be clearly presented in the following detailed description of a preferred embodiment with reference to the drawings. Directional terms mentioned in the following embodiments, such as up, down, left, right, front, or back are only for reference to the directions in the attached drawings, and the directional terms used are to illustrate and not to limit the disclosure.

Reference will now be made in detail to the exemplary embodiments of the disclosure, examples of which are illustrated in the accompanying drawings. Whenever possible, the same reference numerals are used in the drawings and descriptions to refer to the same or similar parts.

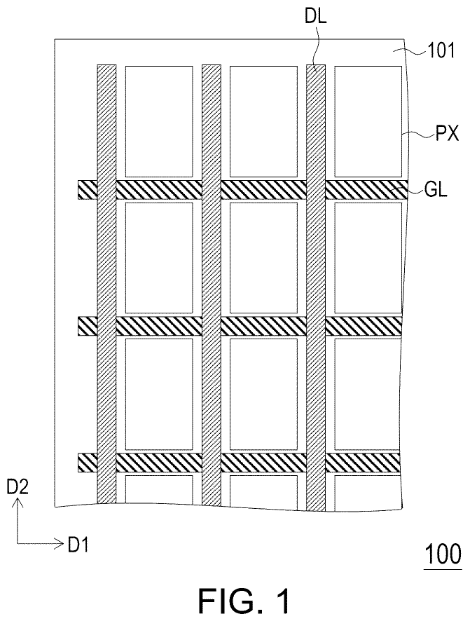

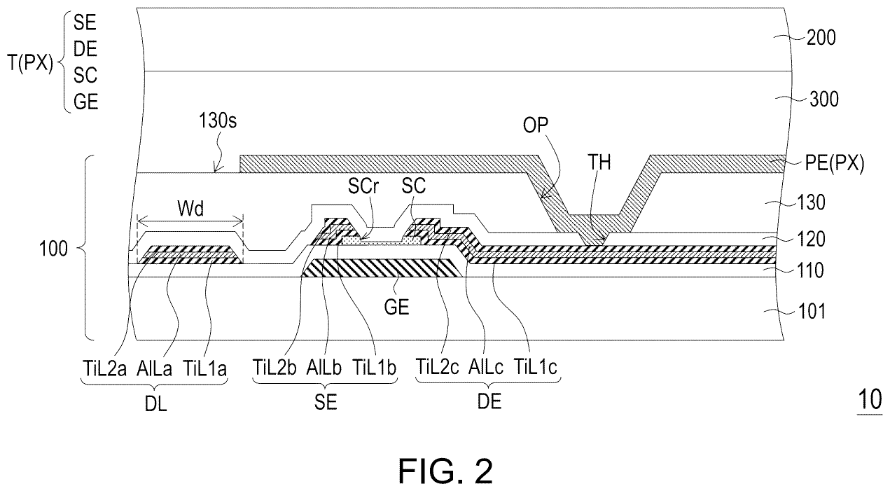

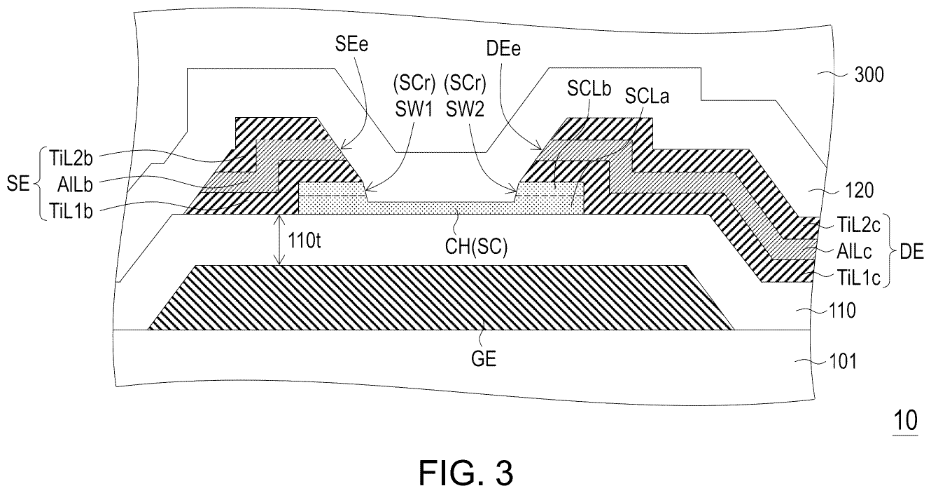

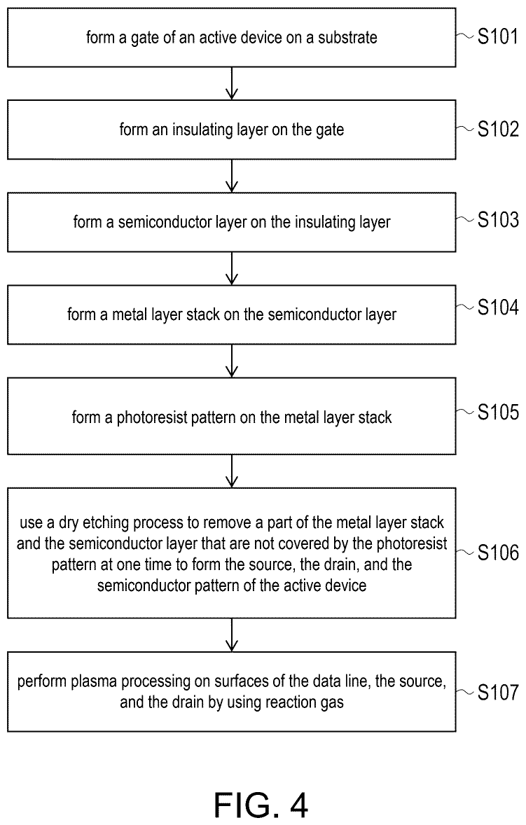

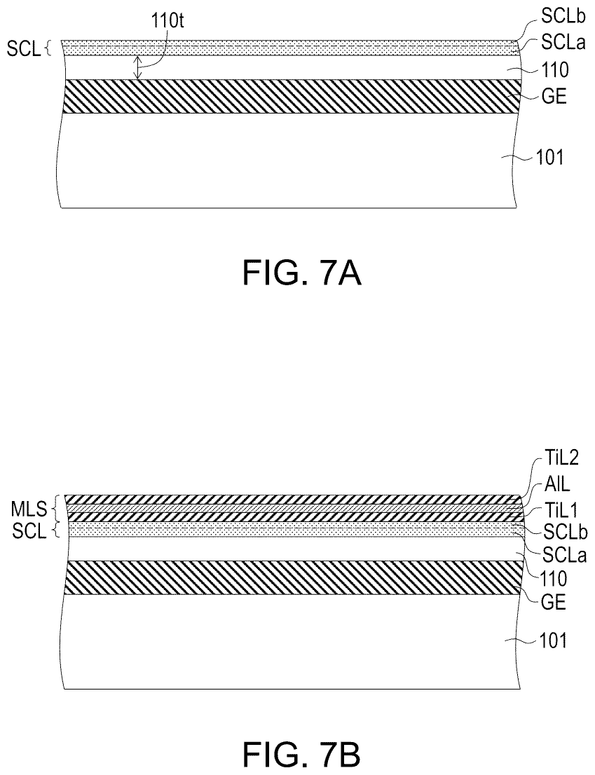

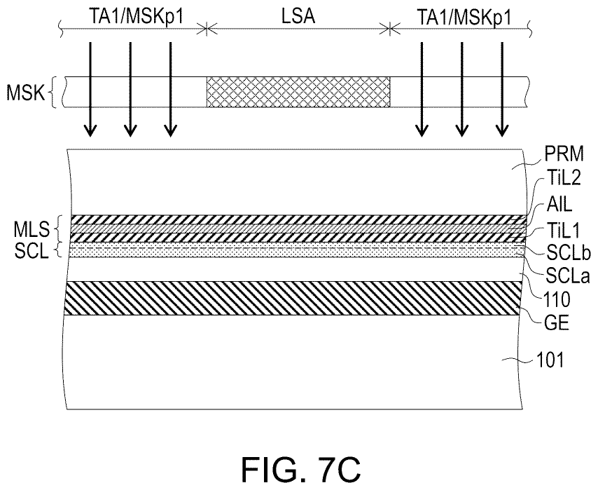

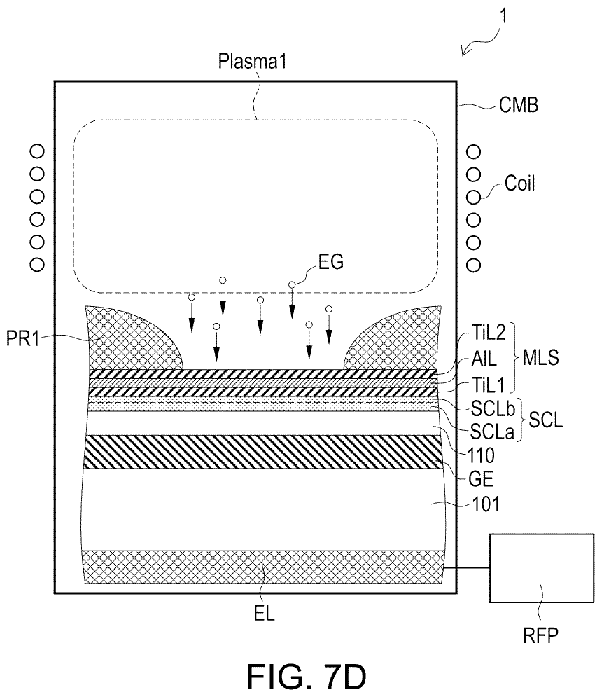

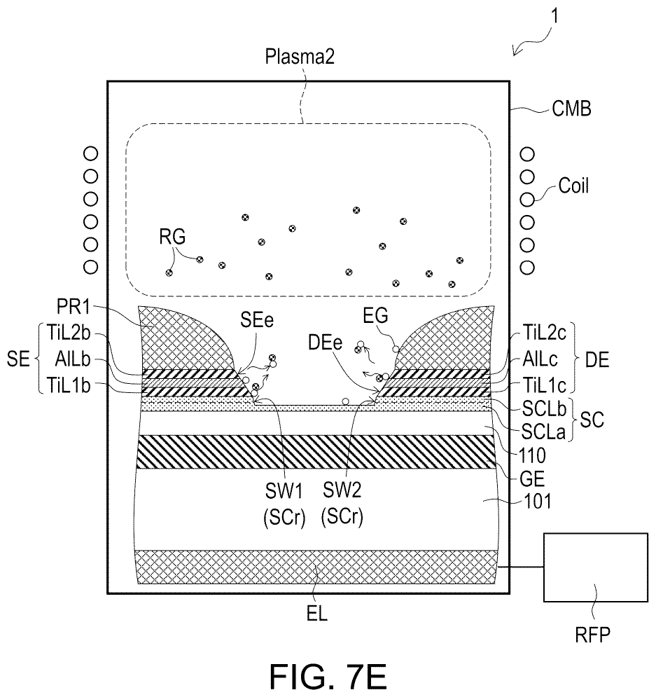

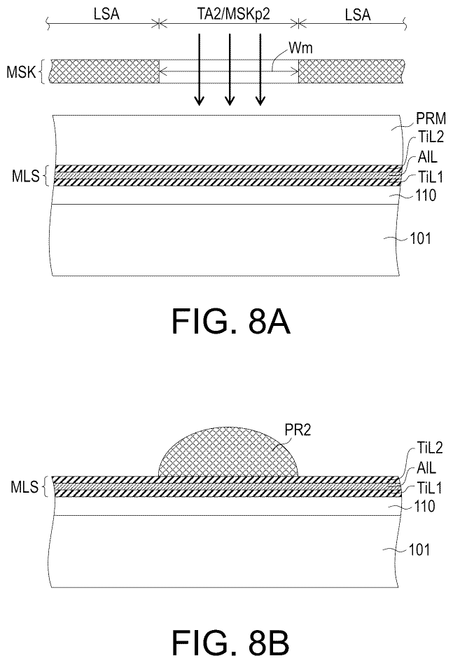

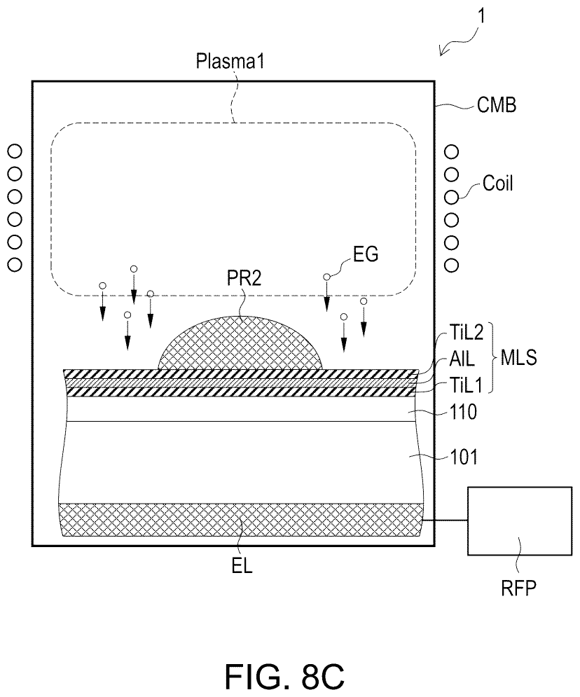

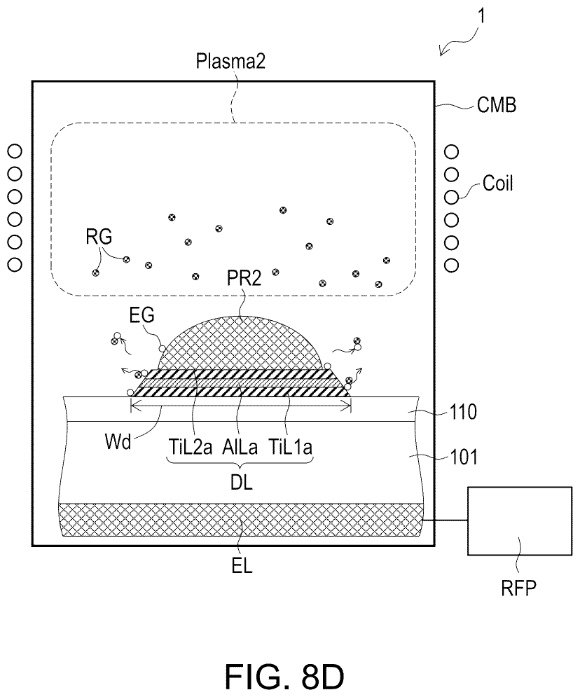

FIG. 1 is a schematic front view of a pixel array substrate according to an embodiment of the disclosure. FIG. 2 is a schematic cross-sectional view of a display panel according to an embodiment of the disclosure. FIG. 3 is an enlarged schematic view of a partial area of FIG. 2. FIG. 4 to FIG. 6 are flow charts of a method of fabricating a pixel array substrate of FIG. 2. FIG. 7A to FIG. 7E and FIG. 8A to FIG. 8D are schematic cross-sectional views of a fabricating process of the pixel array substrate of FIG. 2.

Please refer to FIG. 1 and FIG. 2. A pixel array substrate 100 includes a substrate 101, multiple data lines DL, multiple gate lines GL, and multiple pixel structures PX. In this embodiment, the data lines DL are spaced apart in a direction D1 and extend in a direction D2, and the gate lines GL are spaced apart in the direction D2 and extend in the direction D1, for example. That is, the data lines DL intersect the gate lines GL and define multiple pixel areas. The pixel structures PX are respectively disposed in the pixel areas, and are each electrically connected to one gate line GL and one data line DL. More specifically, the pixel structures PX can be arranged in an array on the substrate 101, for example, arranged in multiple columns and rows in the direction D1 and the direction D2.

In detail, the pixel structure PX includes an active device T and a pixel electrode PE. In this embodiment, a method of forming the active device T may include the following steps: sequentially forming a gate GE, an insulating layer 110, a semiconductor pattern SC, a source SE, and a drain DE on the substrate 101. The semiconductor pattern SC is disposed overlapping the gate GE. The source SE and the drain DE overlap the semiconductor pattern SC and are in electrical contact with two different areas of the semiconductor pattern SC. In this embodiment, the gate GE of the active device T can be selectively disposed below the semiconductor pattern SC to form a bottom-gate thin film transistor (bottom-gate TFT).

The active device T is also covered with a passivation layer 120 and a flat layer 130. The pixel electrode PE of the pixel structure PX is disposed on a surface 130s of the flat layer 130 facing away from the substrate 101, and is electrically connected to the drain DE of the active device T through an opening OP of the flat layer 130 and a contact hole TH of the passivation layer 120.

It should be noted that the gate GE, the insulating layer 110, the passivation layer 120, and the flat layer 130 can be realized by any gate, any insulating layer, any passivation layer, and any flat layer, respectively, for display panels, as known to any person skilled in the art, and the gate GE, the insulating layer 110, the passivation layer 120, and the flat layer 130 can be formed by any of the methods known to any person skilled in the art, respectively, and therefore will not be repeated in the following.

In this embodiment, a material of the insulating layer 110 includes SiNₓ or SiO₂. A material of the semiconductor pattern SC includes amorphous silicon semiconductor. For example, the semiconductor pattern SC may be a stacked structure of a first semiconductor layer SCLa and a second semiconductor layer SCLb, and the first semiconductor layer SCLa and the second semiconductor layer SCLb may be an amorphous silicon semiconductor layer and an n-type amorphous silicon semiconductor layer respectively. The first semiconductor layer SCLa can be used as an active layer of the semiconductor pattern SC, and the second semiconductor layer SCLb can be used as an ohmic contact layer of the semiconductor pattern SC.

In this embodiment, the source SE and drain DE of the data line DL and the active device T can be the same film layer, and this film layer is a metal layer stack. For example, the data line DL may include a first titanium layer TiL1a, an aluminum layer AlLa, and a second titanium layer TiL2a sequentially stacked on the substrate 101. The source SE may include a first titanium layer TiL1b, an aluminum layer AlLb, and a second titanium layer TiL2b sequentially stacked on the substrate 101. The drain DE may include a first titanium layer TiL1c, an aluminum layer AlLc, and a second titanium layer TiL2c sequentially stacked on the substrate 101. A thickness of the first titanium layer and the second titanium layer can be greater than or equal to 200 Å, and a thickness of the aluminum layer can be greater than or equal to 1000 Å, but is not limited thereto.

Please refer to FIG. 2 and FIG. 3. It should be noted that in this embodiment, the semiconductor pattern SC has a groove SCr between the source SE and the drain DE, and a source edge SEe of the source SE and a drain edge DEe of the drain DE define two opposite side walls SW1 and SW2 of the groove SCr respectively. More specifically, the sidewall SW1 and the sidewall SW2 of the groove SCr of the semiconductor pattern SC are substantially aligned with the source edge SEe and drain edge DEe respectively.

It should be noted that in this embodiment, the source SE and drain DE which are stacked by titanium layer, aluminum layer, and titanium layer and the groove SCr of the semiconductor pattern SC formed by amorphous silicon semiconductor can be formed all at once in the same dry etching process. Compared with the conventional process that requires a combination of dry etching and wet etching, the process in this embodiment allows for smaller critical dimensional bias (CD bias) in a channel CH, the source SE, and the drain DE of the semiconductor pattern SC. More specifically, the combination of materials and processes used in the fabricating process of this embodiment enables the fabricating capability of fine line widths.

A method of fabricating a pixel array substrate 100 is exemplarily described below. Referring to FIG. 4 and FIG. 7A, first, a gate GE is formed on a substrate 101 (i.e., step S101). Next, an insulating layer 110 covering the gate GE is formed on the substrate 101 (i.e., step S102). A thickness 110t of the insulating layer 110 is not less than 1300 Å.

Next, a semiconductor layer SCL is formed on the insulating layer 110 (i.e., step S103). In this embodiment, the forming step of the semiconductor layer SCL may include sequentially forming a first semiconductor layer SCLa and a second semiconductor layer SCLb on the insulating layer 110. A material of the first semiconductor layer SCLa is, for example, undoped amorphous silicon semiconductor, that is, intrinsic semiconductor. A material of the second semiconductor layer SCLb is, for example, n-type amorphous silicon semiconductor.

Referring to FIG. 4 and FIG. 7B, next, a metal layer stack MLS is formed on the semiconductor layer SCL (i.e., step S104). In this embodiment, the forming step of the metal layer stack MLS may include sequentially forming a first titanium layer TiL1, an aluminum layer AlL, and a second titanium layer TiL2 on the substrate 101.

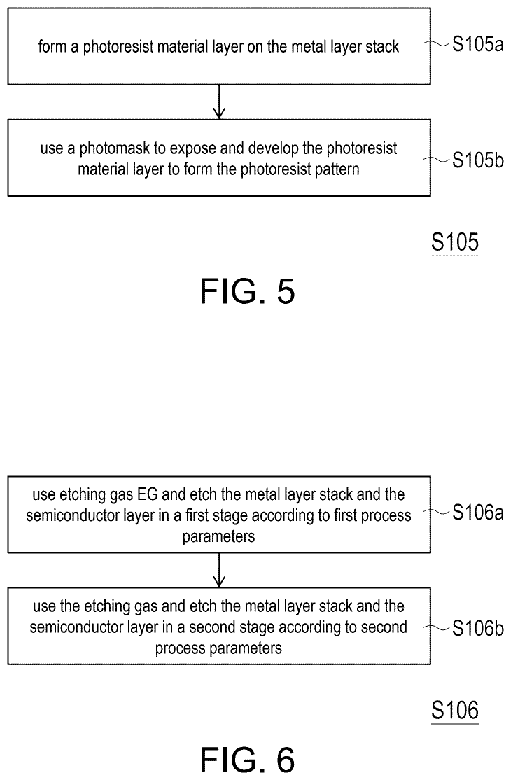

Referring to FIG. 4, FIG. 5, FIG. 7C, and FIG. 7D, a photoresist pattern PR1 is formed on the metal layer stack MLS (i.e., step S105). For example, the step S105 for forming the photoresist pattern PR1 may include forming a photoresist material layer PRM on the metal layer stack MLS (i.e., step S105a, as shown in FIG. 7C) and using a photomask MSK to expose and develop the photoresist material layer PRM to form the photoresist pattern PR1 (i.e., step S105b, as shown in FIG. 7C and FIG. 7D). In this embodiment, the photoresist material layer PRM is, for example, a negative photoresist layer, and a light-transmitting area TA1 of the photomask MSK can define the photoresist pattern PR1. In detail, a part of the photoresist material layer PRM that overlaps the light-transmitting area TA1 can be retained after development because it receives sufficient exposure, while the other part of the photoresist material layer PRM that overlaps a light-shielding area LSA is not substantially exposed and is washed away after development.

In other words, in this embodiment, the light-transmitting area TA1 can be used as a photomask pattern MSKp1 corresponding to the photoresist pattern PR1 on the photomask MSK. However, the disclosure is not limited thereto. In other implementations, the photoresist material layer PRM can be a positive photoresist layer, and the light-shielding area LSA can be used as a photomask pattern corresponding to the photoresist pattern PR1 on the photomask MSK.

On the other hand, in this embodiment, the data line DL in FIG. 2 and the source SE and the drain DE of the active device T are of the same film layer, that is, they are both made of the same metal layer stack MLS. Thus, in addition to contacting the semiconductor layer SCL, the metal layer stack MLS also contacts part of the insulating layer 110. Referring to FIG. 4, FIG. 8A, and FIG. 8B, in the step S105 for forming the photoresist pattern PR1, a photoresist pattern PR2 corresponding to the data line DL is also formed. In other words, the photomask MSK also has a photomask pattern MSKp2 (i.e., a light-transmitting area TA2) corresponding to the data line DL.

Please refer to FIG. 4, FIG. 7D, and FIG. 7E. After the photoresist pattern PR1 is formed, the dry etching process is used to remove a part of the metal layer stack MLS and the semiconductor layer SCL that are not covered by the photoresist pattern PR1 at one time to form the source SE, the drain DE, and the semiconductor pattern SC of the active device T (i.e., step S106). For example, in this embodiment, the step of the dry etching process may include etching the metal layer stack MLS and the semiconductor layer SCL using etching gas EG.

In this embodiment, the etching process of the metal layer stack MLS is performed using a dry etching equipment 1. The dry etching equipment 1 is, for example, an etching equipment using inductively coupled plasma (ICP) as a plasma source, and includes, for example, a chamber CMB, an electrode coil Coil, and a lower electrode plate EL. The electrode coil Coil can be electrically coupled to a radio frequency (RF) power source (not shown), and is used to form high-density plasma in the cavity CMB. The lower electrode plate EL disposed in the cavity CMB is electrically coupled to another radio frequency power supply RFP and is used to provide an etching bias.

During the etching process, the substrate 101 and the metal layer stack MLS and the semiconductor layer SCL formed thereon are suitable for being placed on the lower electrode plate EL. The etching gas EG enters the cavity CMB and is dissociated in the space surrounded by the electrode coil Coil to form plasmatized etching gas ions (i.e., plasma Plasma1). The bias control of the lower electrode plate EL allows the ionized etching gas EG to have anisotropic etching capabilities (as shown in FIG. 7D). In this embodiment, the etching gas EG includes, for example, Cl₂.

In this embodiment, the step S106 of using the dry etching process to remove the part of the metal layer stack MLS and the semiconductor layer SCL that are not covered by the photoresist pattern PR1 at one time can be divided into two stages. In the two stages, the dry etching equipment 1 is set with different process parameters. Referring to FIG. 6 at the same time, for example, first, the etching gas EG is used and the metal layer stack MLS and the semiconductor layer SCL are etched in a first stage according to first process parameters (i.e., step S106a). The first process parameters include first cavity pressure, first bias power, and first etching time. Next, the etching gas EG is used and the metal layer stack MLS and the semiconductor layer SCL are etched in a second stage according to second process parameters (i.e., step S106b). The second process parameters include second cavity pressure, second bias power, and second etching time. It should be noted that the second bias power set during the second stage etching is smaller than the first bias power set during the first stage etching, the second cavity pressure is smaller than the first cavity pressure, and the second etching time is smaller than the first etching time.

In particular, the etching in the first stage is mainly for patterning the metal layer stack MLS. For example, a part of the second titanium layer TiL2, a part of the aluminum layer AlL, and a part of the first titanium layer TiL1 are removed to form a stacked structure of the second titanium layer TiL2b, the aluminum layer, and the first titanium layer TiL1b, and a stacked structure of the second titanium layer TiL2c, an aluminum layer AlLc, and the first titanium layer TiL1c respectively. The etching in the second stage is mainly to adjust the configuration of etched sidewalls formed by the metal layer stack MLS after the etching in the first stage, for example, inclination of a sidewall surface (i.e., the source edge SEe) of the second titanium layer TiL2b, the aluminum layer AlLb, and the first titanium layer TiL1b and a sidewall surface (i.e., the drain edge DEe) of the second titanium layer TiL2c, the aluminum layer AlLc, and the first titanium layer TiL1c in FIG. 7E.

After completing the dry etching in the second stage, the stacked structure of the second titanium layer TiL2b, the aluminum layer AlLb, and the first titanium layer TiL1b forms the source SE of the active device T, and the stacked structure of the second titanium layer TiL2c, the aluminum layer AlLc, and the first titanium layer TiL1c forms the drain DE of active device T.

On the other hand, in step S106, a part of the metal layer stack MLS that is not covered by the photoresist pattern PR2 is removed and the data line DL is formed (as shown in FIG. 8C and FIG. 8D). The data line DL is a stacked structure of the second titanium layer TiL2a, the aluminum layer AlLa, and the first titanium layer TiL1a. Specifically, the light-transmitting area TA2 of the photomask MSK in FIG. 8A has a width Wm, the data line DL formed in FIG. 8D has a width Wd, and a difference value between the width Wm and the width Wd is less than or equal to 0.6 microns. Preferably, the difference value between the width Wm and the width Wd may be less than or equal to 0.3 microns. In other words, the difference between the actual linewidth of the data line DL formed by the aforementioned material structure and the matching dry etching process and the design value of the linewidth of the corresponding photomask pattern (i.e., CD bias) is not significant.

It should be noted that after the dry etching process for the metal layer stack MLS is completed, a part of the semiconductor layer SCL between the source SE and the drain DE is removed together to form the semiconductor pattern SC having the groove SCr. That is, the dry etching process is to etch from the metal layer stack MLS to the semiconductor layer SCL at one time. Thus, the formed source edge SEe of the source SE and the drain edge DEe of the drain DE can define the sidewalls SW1 and SW2 of the groove SCr of the semiconductor pattern SC. In other words, the sidewall SW1 and the sidewall SW2 of the groove SCr of the semiconductor pattern SC can be substantially aligned with the source edge SEe and drain edge Dee respectively.

From another perspective, in this embodiment, formation positions of the source edge SEe of the source SE and the drain edge DEe of the drain DE can define a length of the channel CH (as shown in FIG. 3) of the semiconductor pattern SC. Since the process technology allows the formed source SE and drain DE to have a smaller critical-dimension bias (CD bias), that is, the difference between the actual produced size and the designed value is small, the length of the channel CH of the formed semiconductor pattern SC is also not much different from the design value. As a result, the design margin of the semiconductor pattern SC may be increased. For example, in high-resolution pixel structure design, if the length of the channel of the semiconductor pattern needs to be further reduced, the process technology of this embodiment may ensure that the formed semiconductor pattern will not cause leakage problems due to process errors.

Please refer to FIG. 4, FIG. 7E, and FIG. 8D. After completing the dry etching process of the metal layer stack MLS and the semiconductor layer SCL in FIG. 7D and FIG. 8C, a plasma treatment process is performed on surfaces of the source SE, the drain DE, the semiconductor pattern SC, and the data line DL by using reaction gas RG (i.e., step S107). The reaction gas RG includes, for example, CF₄ and O₂. In this step, the reaction gas RG that enters the cavity CMB is dissociated in the space surrounded by the electrode coil Coil to form plasmatized reaction gas ions (i.e., plasma Plasma2).

The ionized reaction gas RG reacts with the surfaces of the source SE, the drain DE, the semiconductor pattern SC, the data line DL, the photoresist pattern PR1, and the photoresist pattern PR2 or the etching gas EG adsorbed thereon to form reaction products (such as Al₃O₂, AlCl₃ or AlF₃) and then discharged out of the cavity CMB. In this way, the risk of metal corrosion caused by the residual etching gas EG in the source SE, the drain DE, and the data line DL may be further reduced, which helps to improve the production yield and reliability of the active device T and the data line DL.

Referring to FIG. 2, after forming the active device T and the data line DL, the passivation layer 120 and the flat layer 130 covering the active device T and the data line DL are sequentially formed on the substrate 101. Next, the pixel electrode PE is formed on the flat layer 130. The pixel electrode PE is electrically connected to the drain DE of the active device T through the opening OP of the flat layer 130 and a contact hole TH2 of the passivation layer 120. At this point, the production of the pixel array substrate 100 is completed.

In this embodiment, the pixel array substrate 100 is adapted to be assembled with another substrate 200, and a liquid crystal layer 300 is filled between the two to form a display panel 10. That is, the pixel array substrate 100 of this embodiment can be used as one of the substrates of the liquid crystal display panel. For example, the substrate 200 may be provided with a color filter layer (not shown) and/or a common electrode layer (not shown), but is not limited thereto. In some embodiments, the common electrode layer may be disposed on the pixel array substrate 100. An electric field generated between the common electrode layer and the pixel electrode PE is suitable for driving multiple liquid crystal molecules (not shown) of the liquid crystal layer 300 to rotate to form an alignment state corresponding to the direction and intensity of the electric field. By changing the arrangement state of the liquid crystal molecules, a polarization state of light passing through the liquid crystal layer 300 is changed to form a light emission brightness corresponding to the arrangement state.

To sum up, in the method of fabricating the pixel array substrate according to an embodiment of the disclosure, a metal layer stack composed of two titanium layers and one aluminum layer is formed on the amorphous silicon semiconductor layer. The channel, the source, and the drain of the semiconductor pattern formed by using the dry etching process to remove a part of the metal layer stack and a part of the amorphous silicon semiconductor layer at one time may have a smaller critical-dimension bias (CD bias), helping to increase the design margin of the component line width of the pixel array substrate.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A method of fabricating a pixel array substrate, comprising:
forming a semiconductor layer on a substrate, wherein a material of the semiconductor layer comprises amorphous silicon semiconductor;
forming a metal layer stack on the semiconductor layer, wherein the metal layer stack comprises a first titanium layer, an aluminum layer, and a second titanium layer;
forming a photoresist pattern on the metal layer stack; and
removing a part of the metal layer stack and the semiconductor layer not covered by the photoresist pattern at one time using a dry etching process to form a source, a drain, and a semiconductor pattern of an active device, wherein the source and the drain have a source edge and a drain edge opposite to each other respectively, the semiconductor pattern has a groove between the source and the drain, and the source edge and the drain edge define two opposite side walls of the groove respectively.

2. The method of fabricating the pixel array substrate according to claim 1 further comprising:
before forming the semiconductor layer, forming an insulating layer on the substrate; and
forming a gate of the active device on the substrate, the insulating layer covering the gate, wherein the metal layer stack is in contact with a part of the insulating layer, and after the metal layer stack and the part of the semiconductor layer are removed, a data line is formed.

3. The method of fabricating the pixel array substrate according to claim 2, wherein a thickness of the insulating layer is not less than 1300 Å.

4. The method of fabricating the pixel array substrate according to claim 2, wherein a material of the insulating layer comprises SiNₓ or SiO₂.

5. The method of fabricating the pixel array substrate according to claim 2 further comprising:
performing a plasma treatment process on surfaces of the data line, the source, and the drain using reaction gas.

6. The method of fabricating the pixel array substrate according to claim 5, wherein the reaction gas comprises CF₄ and O₂.

7. The method of fabricating the pixel array substrate according to claim 2, wherein forming the photoresist pattern comprises:
forming a photoresist material layer on the metal layer stack; and
exposing and developing the photoresist material layer using a photomask to form the photoresist pattern, wherein the photomask has a photomask pattern corresponding to the data line, and a difference value between a width of the photomask pattern and a width of the data line is less than or equal to 0.6 microns.

8. The method of fabricating the pixel array substrate according to claim 1, wherein the dry etching process comprises:
etching the metal layer stack and the semiconductor layer using etching gas, the etching gas comprising Cl₂.

9. A pixel array substrate, comprising:
a substrate; and
a plurality of active devices, disposed on the substrate, each of the active devices comprising a gate, a semiconductor pattern, a source, and a drain, the gate being located between the semiconductor pattern and the substrate, and the drain and the source being in contact with two different areas of the semiconductor pattern respectively,
wherein a material of the semiconductor pattern comprises amorphous silicon semiconductor, the source and the drain each comprises a first titanium layer, an aluminum layer, and a second titanium layer sequentially stacked on the semiconductor pattern, the source and the drain have a source edge and a drain edge opposite to each other respectively, the semiconductor pattern has a groove located between the source and the drain, and the source edge and the drain edge define two opposite side walls of the groove respectively.

10. The pixel array substrate according to claim 9 further comprising:
an insulating layer, disposed between the gate and the semiconductor pattern;
a data line, disposed on the insulating layer, wherein the source, the drain, and the data line are on the same film layer.
